(19) United States
(12) Patent Application Publication
(10) Pub. No.: US 2013/0249102 A1
(43) Pub. Date: Sep. 26, 2013

(54) SEMICONDUCTOR DEVICE WITH STRENGTHENED INTER-WIRE AIR GAP STRUCTURES

(71) Applicants: Shinichi NAKAO, Kanagawa-ken (JP); Ichiro Mizushima, Kanagawa-ken (JP)

(72) Inventors: Shinichi NAKAO, Kanagawa-ken (JP); Ichiro Mizushima, Kanagawa-ken (JP)

(73) Assignee: Kabushiki Kaisha Toshiba, Tokyo (JP)

(21) Appl. No.: 13/607,695

(22) Filed: Sep. 8, 2012

(30) Foreign Application Priority Data
Mar. 21, 2012 (JP) P2012-064349

(51) Int. Cl. H01L 23/48; H01L 21/768

(52) U.S. Cl. 257/773; 438/619; 257/E23.01; 257/E21.581

(57) ABSTRACT

A semiconductor device with a plurality of wires wherein at least some of the regions between wires (inter-wire regions) contain an air gap region formed by capping the wires and inter-wire regions with an insulator film using a film coating process, for example chemical vapor deposition. The existence, size, and shape of the air gap depend upon the film coating parameters and the spacing between wires.

### CROSS-REFERENCE TO RELATED APPLICATION

This application is based upon and claims the benefit of priority from Japanese Patent Application No. 2012-064349, filed Mar. 21, 2012; the entire contents of which are incorporated herein by reference.

### FIELD

Embodiments described herein relate generally to a semiconductor device.

### BACKGROUND

Recently, as a method to reduce inter-wire capacitance, researchers have been investigating the “air gap” technique wherein an empty cavity is formed between wires in place of an insulator material. An air gap can be formed in such a manner that wires are formed on a substrate and, thereafter, an insulation film with poor embedding properties is deposited over the whole surface of the substrate by plasma CVD (Chemical Vapor Deposition). When an insulation film with poor embedding properties is deposited the resulting film will have unfilled voids and pockets which will form an air gap of sorts between the wires. However, depositing a film with unfilled internal voids and pockets has the drawback that the strength of the inter-wire insulator region is deteriorated. When an air gap structure is formed by plasma CVD, the upper end of the air gap is formed into a pointed shape and hence becomes an initiation point for cracks which makes it more likely that cracks will be generated in the insulation film.

### DESCRIPTION OF THE DRAWINGS

FIG. 1A and FIG. 1B are cross-sectional views showing the structure of a semiconductor device according to a first embodiment.

FIG. 2A and FIG. 2B are cross-sectional views showing the structure of a semiconductor device according to a second embodiment.

FIG. 3 is a cross-sectional view showing the structure of a semiconductor device according to a third embodiment.

FIG. 4 is a cross-sectional view showing the structure of a semiconductor device according to a fourth embodiment.

### DETAILED DESCRIPTION

A semiconductor device with improved inter-wire region strength is described.

In general, the disclosed semiconductor device includes a semiconductor substrate. The device also includes a plurality of wires, each of which includes a wire material layer formed on the semiconductor substrate, and an insulation film formed on an upper surface or side surfaces of the wire material layer. The device also includes a cap insulation film formed on the wires such that an air gap is formed between the wires. The height of the air gap may be set lower than the height of upper surface of the metal wire film.

### First Embodiment

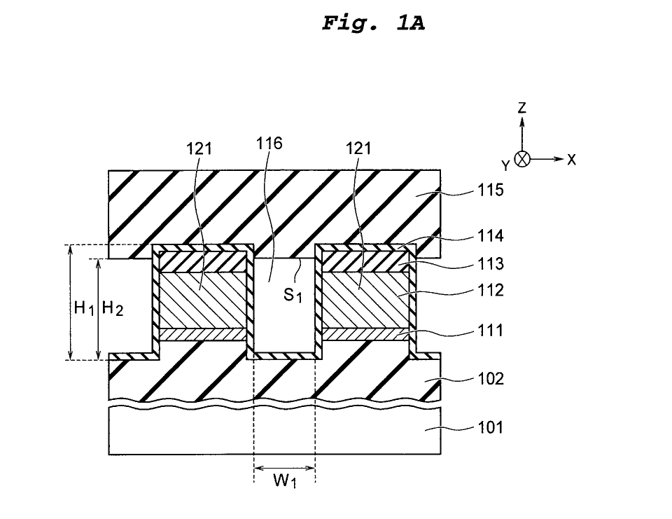

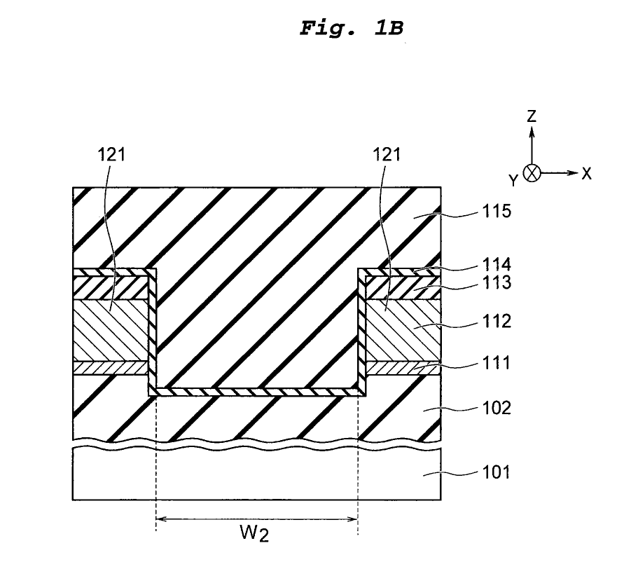

FIG. 1A and FIG. 1B are cross-sectional views showing the structure of a semiconductor device according to the first embodiment. FIG. 1A and FIG. 1B show the different cross sections of the same semiconductor device.

The semiconductor device shown in FIG. 1A and FIG. 1B includes a semiconductor substrate 101, an interlayer insulation film 102 which is formed on the semiconductor substrate 101, and a plurality of wires 121 which are formed on the interlayer insulation film 102. Each wire 121 includes a metal liner film 111, a metal wire film 112, a hard mask film 113, and an insulation liner film 114. The semiconductor device shown in FIG. 1A and FIG. 1B also includes a cap insulation film 115 and air gaps 116.

The semiconductor substrate 101 is a silicon substrate, for example. The interlayer insulation film 102 is a silicon oxide film, for example. In FIG. 1A and FIG. 1B, the X and Y directions which are parallel to a main surface of the semiconductor substrate 101 and are orthogonal to each other, and the Z direction orthogonal to the main surface of the semiconductor substrate 101 are indicated.

The wires 121 extend in the Y direction (in the Fig. into and out of the page) and are arranged adjacent to each other in the X direction. FIG. 1A shows the wires 121 with a relatively short inter-wire distance W₁, and FIG. 1B shows the wires 121 with a relatively larger inter-wire distance W₂. In this example, the distance W₁ is set to be less than 200 nm, and the distance W₂ is set to be greater than 200 nm. The wires 121 shown in FIG. 1A are examples of first and second wires of this disclosure. Further, the wires 121 shown in FIG. 1B are examples of third and fourth wires of this disclosure.

The metal liner film 111 and the metal wire film 112 are formed in order on the interlayer insulation film 102. The metal liner film 111 is formed of a TiN (titanium nitride) film, for example. The metal wire film 112 is formed of an Al (aluminum) film or a W (tungsten) film, for example. The metal liner film 111 and the metal wire film 112 are examples of wire material layers of this disclosure.

The hard mask film 113 is formed on an upper surface of the metal wire film 112. The hard mask film 113 is formed of a silicon nitride film or a silicon oxide film, for example. The insulation liner film 114 is formed on side surfaces of the metal liner film 111, side surfaces of the metal wire film 112, side surfaces and an upper surface of the hard mask film 113, and an upper surface of the interlayer insulation film 102 between the wires 121. The insulation liner film 114 is formed of a silicon nitride film, for example. The hard mask film 113 and the insulation liner film 114 are examples of insulation films of this disclosure.

The wire 121 can be formed in such a manner that the metal liner film 111, the metal wire film 112 and the hard mask film 113 are formed as stacked layers over the whole surface of the interlayer insulation film 102 then patterned and etched. The insulation liner film 114 is formed over interlayer insulation film 102 and wire 121.

A cap insulation film 115 is formed over, and spans the wires 121 such that the air gap 116 is formed between the wires 121 and the cap layer 115 and interlayer insulation film 102. The cap insulation film 115 is formed of a SiOCH film (carbon doped silicon oxide film), for example. In this embodiment, the cap insulation film 115 is formed by forming the cap insulation film 115 on the whole surface of the interlayer insulation film 102 by coating after forming the wires 121. As a result, the air gap 116 is formed between the wires 121.

Symbol S₁ indicates the upper surface of the air gap 116. The upper surface S₁ of the air gap 116 spans between from one side surface of one wire 121 to another side surface of a different wire 121. The air gap 116 shown in FIG. 1A is an example of the first air gap of this disclosure.

### (1) Structure of Air Gap 116.

As described above, the cap insulation film 115 is formed by a coating method. As a result, the upper surface S₁ of the air gap 116 is a flat surface. Accordingly, the air gap 116 does not have an initiation point of cracks. Accordingly, this embodiment can suppress the generation of cracks in the cap insulation film 115.

By forming the cap insulation film 115 by a coating method, the cap insulation film 115 partially enters the space between the wires 121. As a result, a height H₂ of the air gap 116 is lower than the height H₁ of the upper surface of the wire 121 (H₂<H₁). This structure increases the strength of the inter-wire region.

Accordingly, in this embodiment, by setting the height H₂ lower than the height H₁, the reduction in strength of the inter-wire region caused by the presence of air gap 116 can be mitigated. Further, by forming the upper surface S₁ of the air gap 116 into a flat surface, an initiation point for potential cracks can be eliminated so that the generation of cracks in the cap insulation film 115 can be suppressed.

The height H₂ of the upper surface S₁ of the air gap 116 may be set higher or lower than the upper surface of the metal wire film 112. However, in this embodiment, the height H₂ is set higher than the height of the upper surface of the metal wire film 112. This is done to keep inter-wire capacitance low.

In this embodiment, by forming the cap insulation film 115 by coating, the whole inter-wire region below the cap insulation film 115 can be formed into the air gap 116. This structure has an advantage that the volume of the air gap 116 can be increased so that inter-wire capacitance can be reduced. Although the term “air gap” is used herein, the gap may be a vacuum gap, such that the pressure inside the gap or void is less than atmospheric pressure, and the gaseous constituents in the gap may comprise air, or combinations of gasses used in the fabrication of the semiconductor device. By forming the cap insulation film 115 by a coating method, the air gap 116 can be formed only between the wires 121 with a relatively short inter-wire distance. FIG. 1A shows a mode where the air gap 116 is formed between the wires 121 with the short inter-wire distance W₁. FIG. 1B shows a mode where the space between the wires 121 is the relatively long inter-wire distance W₂ and the space between wires 121 is embedded or filled with the cap insulation film 115. The cap insulation film is preferably formed using a spin on dielectric process to form a dielectric such as silicon oxide.

The upper limit of the inter-wire distance between which the air gap 116 can be formed can be adjusted by varying the dry time and the heating temperature used during the film forming process. In this embodiment, the upper limit of the inter-wire distance is set to approximately 200 nm. This is done because once the inter-wire distance becomes longer than approximately 200 nm, no significant further reduction of inter-wire capacitance can be achieved in general, and it is more desirable to ensure strength of the inter-wire region. Accordingly, in this embodiment, by setting the above-mentioned upper limit to approximately 200 nm, wiring spaces with an inter-wire distance of more than 200 nm are filed with the cap insulation film 115, but voids, to provide void or air gap insulators, occurs where the gap is less than 200 nm.

### (2) Advantageous Effects Acquired By First Embodiment

As described above, the height H₂ of the upper end (upper surface S₁) of the air gap 116 is set lower than the height H₁ of the upper surface of the wire 121 (H₂<H₁). By having the insulation cap film 115 fill a portion of the space between wires, the deterioration of strength of the inter-wire region caused by the air gap 116 can be reduced.

The wires 121 of this embodiment are formed on the interlayer insulation film 102 but, the wires 121 of this embodiment could be directly formed on the semiconductor substrate 101 without an intervening interlayer insulator film 102. Further, the layer directly below the wire 121 may be a layer other than the semiconductor substrate 101 or the interlayer insulation film 102, if device structure so requires.

A wire material layer which constitutes the wire 121 in this embodiment is formed of a conductive layer which is typically a metal conductive layer. However, the wire material layer may also be formed of a semiconductor layer such as a polysilicon layer, for example.

### Second Embodiment

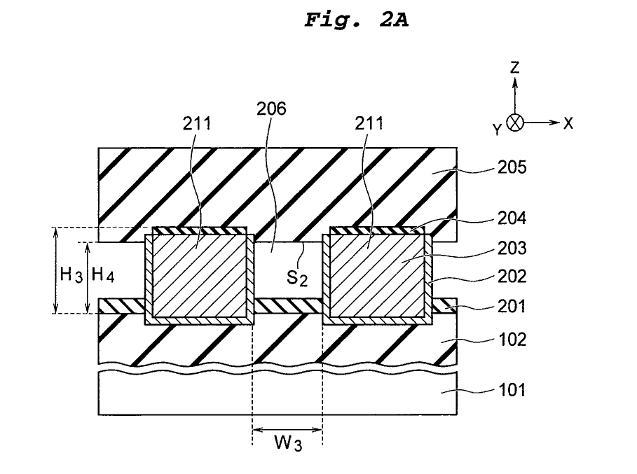

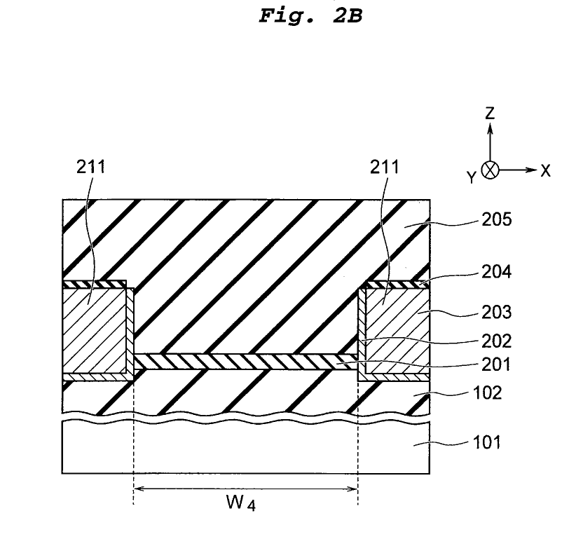

FIG. 2A and FIG. 2B are cross-sectional views showing the structure of a semiconductor device according to the second embodiment. FIG. 2A and FIG. 2B show the different cross sections of the same semiconductor device.

The semiconductor device shown in FIG. 2A and FIG. 2B includes a semiconductor substrate 101, an interlayer insulation film 102 which is formed on the semiconductor substrate 101, an etching stop film 201 which is formed on the interlayer insulation film 102, and a plurality of wires 211 which are formed on the interlayer insulation film 102. Each wire 211 is a damascene wire which includes a barrier metal film 202, a wire film 203 and a passivation film 204. The semiconductor device shown in FIG. 2A and FIG. 2B also includes a cap insulation film 205 and FIG. 2A further includes an air gap 206.

In the same manner as the wires 121 shown in FIG. 1A and FIG. 1B, the wires 211 extend in the Y direction and are arranged adjacent to each other in the X direction. FIG. 2A shows the wires 211 with a relatively short inter-wire distance W₃, and FIG. 2B shows the wires 211 with a relatively long inter-wire distance W₄. In this embodiment, the distance W₃ is set shorter than 200 nm, and distance W₄ is set longer than 200 nm. The wires 211 shown in FIG. 2A are examples of first and second wires of this disclosure. Further, the wires 211 shown in FIG. 2B are examples of third and fourth wires of this disclosure. The wires 211 shown in FIG. 2A and FIG. 2B are formed on the interlayer insulation film 102 and extend through the etching stop film 201.

The wire film 203 is formed on the interlayer insulation film 102 by way of a barrier metal film 202 which is in contact with the lower surface and side surfaces of the wire film 203. A passivation film 204 is formed on the upper surface of the wire film 203. The barrier metal film 202 is formed of a TiN film or a TaN (tantalum nitride) film, for example. The wire film 203 is formed of a Cu (copper) film, for example. The passivation film 204 is a CuSiN film, for example. The barrier metal film 202 and the wire film 203 are examples of a wire material layer of this disclosure. The passivation film 204 is an example of an insulation film of this disclosure.

The structure shown in FIG. 2A is formed by providing the underlying insulation film 102, and patterning the film using photolithographic and etching techniques to form apertures into which the barrier metal film 202 and the wire film 203 are deposited. Thereafter, portions of these films extending over the field, or upper surfaces, of the insulation film 102 are removed, typically using chemical mechanical polishing techniques. A Sin film is formed over the planarized structure, which is then annealed to form the Metal-Si—N structure of the passivation film. Then, the portion of the SiN and insulation films extending between the wire film 203 regions are etched, to yield the air gap regions between adjacent wire film regions. Thereafter, the overlying passivation film 204, such as a SiN film, is deposited, and the resulting structure is annealed in situ to form a Metal SiN

The wire 211 need not have the passivation film 204. In this case, the wire 211 adopts a structure having no passivation film.

The wire 211 may have an insulation liner film, equivalent to the insulation liner film 114 shown in FIGS. 1A and 1B, together with the passivation film 204 or in place of the passivation film 204. The insulation liner film 114 is an example of the insulation film of this disclosure.

The cap insulation film 205 is formed on the wires 211 such that the air gap 206 is formed between the wires 211. The cap insulation film 205 is formed of a carbon doped silicon oxide film, for example. In this embodiment, in the same manner as the first embodiment, the cap insulation film 205 is formed by forming the cap insulation film 205 on the whole surface of the interlayer insulation film 102 by coating after forming the wires 211. As a result, the air gap 206 is formed between the wires 211 when the space between the wires is less than some distance W₃. By using a spin on dielectric film, the surface tension and/or viscosity of the dielectric material in a liquid form will limit the extension of the dielectric material being deposited from extending inwardly of the gap regions between adjacent wires 211, thus enabling formation of the air gap region between the wires 211.

Symbol S₂ indicates an upper surface of the air gap 206. The upper surface S₂ of the air gap 206 is continuously formed from a side surface of one wire 211 to a side surface of another wire 211 between the wires 211. Accordingly, the air gap 206 of this embodiment is between the wires 211 arranged on both sides of the air gap 206. The air gap 206 shown in FIG. 2A is, in the same manner as the air gap 116 shown in FIG. 1A, an example of the first air gap of this disclosure.

It is noted that the air gap 206 is formed between the wires 211 shown in FIG. 2A, and the air gap 206 is not formed between the wires 211 shown in FIG. 2B.

As described above, in this embodiment, the cap insulation film 205 is formed by a coating method. As the result, the upper surface S₂ of the air gap 206 is a flat surface. Accordingly, in the same manner as the first embodiment, this embodiment can suppress the generation of cracks in the cap insulation film 205.

By forming the cap insulation film 205 by a coating method, the cap insulation film 205 partially enters the space between the wires 211. As the result, a height H₄ of an upper end (upper surface S₂) of the air gap 206 is set lower than a height H₃ of an upper surface of the wire 211 (H₄<H₃). Accordingly, the deterioration in strength (crack resistance) of an inter-wire region caused by the presence of air gap 206 can be mitigated.

### Third Embodiment

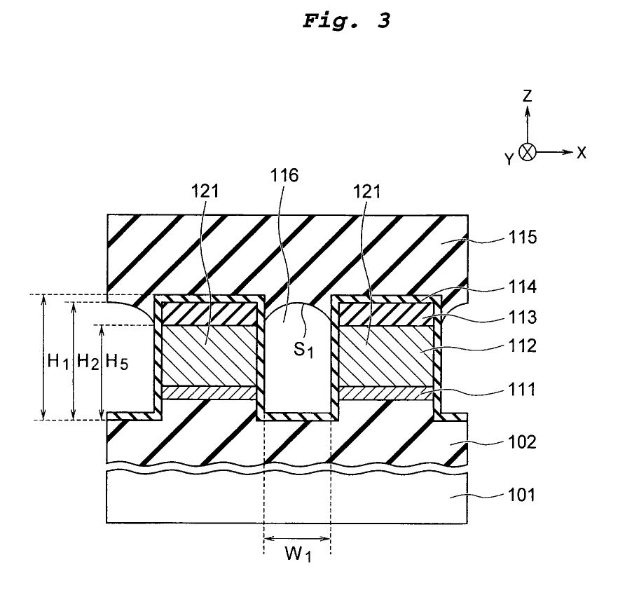

FIG. 3 is a cross-sectional view showing the structure of a semiconductor device according to the third embodiment. The structure shown in FIG. 3 is similar to the structure shown in FIG. 1A, excepting the shape of the upper surface of the air gap.

In the same manner as the first embodiment, a cap insulation film 115 is formed by a coating method. As a result, the upper surface S₁ of the air gap 116 of this embodiment is formed from a side surface of one wire 121 to a side surface of another wire 121 between the wires 121. In contrast with the first embodiment, however, the upper surface S₁ of the air gap 116 of this embodiment is formed into a gently curved surface having an upwardly convex shape. To be more specific, the upper surface S₁ of the air gap 116 is formed into a bowed or arch shape having an upwardly convex cross-sectional shape, which continues in the Y direction. Such structure can be realized by setting an inter-wire distance W₁ somewhat longer than the inter-wire distance W₁ used to fabricate the structure shown in FIG. 1A when forming the cap insulation film 115 by a coating method, for example.

In the same manner as the first embodiment, the upper surface S₁ of the air gap 116 of this embodiment does not have a pointed portion so that the upper surface S₁ does not provide an initiation point of cracks. Accordingly, this embodiment can suppress the generation of cracks in the cap insulation film 115.

Symbol H₂, as used in FIG. 3, indicates the maximum height of the center portion of the upper surface S₁ of the air gap 116. Accordingly, in the same manner as the case shown in FIG. 1A, the symbol H₂ indicates the upper end of the air gap 116. Symbol H₅ indicates the height where the upper surface S₁ of the air gap 116 meets wire 121. In this embodiment, the upper surface S₁ has the upwardly convex shape so that the height H₂ is set higher than the height H₅ (H₂>H₅). In the first embodiment, as depicted in FIG. 1, the height H₂ would equal the height H₅ (H₂=H₅).

By forming the cap insulation film 115 by a coating method, the cap insulation film 115 partially enters the space between the wires 121 of this embodiment. As the result, in the same manner as the first embodiment, the height H₂ of the upper end (the center portion of the upper surface S₁) of the air gap 116 is set lower than height H₁ of an upper surface of the wire 121 (H₂<H₁). Accordingly, the deterioration of strength of an inter-wire region caused by the air gap 116 can be similarly suppressed.

The height H₂ indicates a height from an upper surface of an interlayer insulation film 102 to the center portion of the upper surface S₁, and the height H₅ indicates a height from the upper surface of the interlayer insulation film 102 to the end portion of the upper surface S₁. When the difference between the height H₂ and the height H₅ is small, the upper surface S₁ becomes a gently curved surface, but when the difference between the height H₂ and the height H₅ is large, the upper surface S₁ becomes a curved surface with a steep inclination. To help suppress the generation of cracks in the cap insulation film 115, the upper surface S₁ is formed into a gently curved surface. In this embodiment, the height H₅ is set to ½ or more of the height H₂, for example.

As described above, according to this embodiment, the height H₂ of the upper end (the center portion of the upper surface S₁) of the air gap 116 is set lower than the height H₁ of the upper surface of the wire 121 (H₂<H₁). Accordingly, in this embodiment, in the same manner as the first embodiment, the deterioration in strength of the inter-wire region caused by the air gap 116 can be suppressed by having the insulation cap layer fill a portion of the space between wires 121.

### Fourth Embodiment

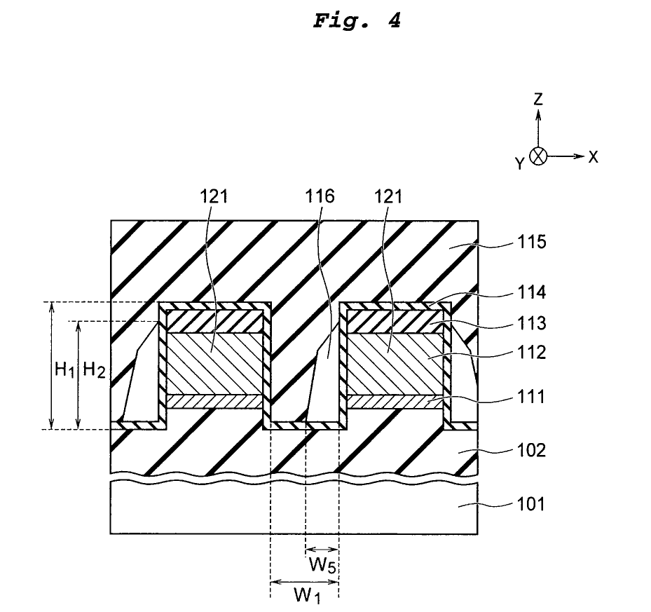

FIG. 4 is a cross-sectional view showing the structure of a semiconductor device according to the fourth embodiment. The structure shown in FIG. 4 corresponds to another modification of the structure shown in FIG. 1A.

The air gap 116 shown in FIG. 1A is brought into contact with the wires 121 arranged on both sides of the air gap 116. But the air gap 116 shown in FIG. 4 is brought into contact with only one of the wires 121 arranged on either sides of the air gap 116. The air gap 116 shown in FIG. 4 is an example of a second air gap of this disclosure.

The air gap 116 shown in FIG. 4 can be realized by setting an inter-wire distance W₁ somewhat greater than the inter-wire distance W₁ used to form the structure shown in FIG. 1A in forming a cap insulation film 115 by a coating method, for example if the distance W₁ in FIG. 1A. Is set to 100 nm or less, then to form the structure in FIG. 4 the spacing between wires 121 would be set to 100 to 200 nm, for example.

Symbol W₅ indicates a width of the air gap 116 in FIG. 4. In this embodiment, the air gap 116 does not span the entire distance between wires 121, hence width W₅ of the air gap 116 is less than the inter-wire distance W₁ (W₅<W₁). In forming the air gap 116 by a coating method, whether the air gap 116 is formed on a side surface of the wire 121 on one side or on a side surface of the wire 121 on the other side is decided randomly.

In this embodiment, by forming the cap insulation film 115 by a coating method, the cap insulation film 115 partially enters between the wires 121. As the result, in the same manner as the first embodiment, a height H₂ of an upper end of the air gap 116 is set lower than a height H₁ of an upper surface of the wire 121 (H₂<H₁). Accordingly, in this embodiment, the opening portion between the wires 121 can be firmly closed by the cap insulation film 115 and hence, the deterioration of strength of an inter-wire region caused by the air gap 116 can be suppressed.

In this embodiment, the air gap 116 is in contact with only the wire 121 on one side, and the cap insulation film 115 enters between the air gap 116 and the wire 121 on the other side. Accordingly, this embodiment can further increase strength of an inter-wire region due to the entering of the cap insulation film 115.

Further, the air gap 116 of this embodiment has an upper end at an interface portion with the wire 121 and hence, in the same manner as the first embodiment, an upper surface of the air gap 116 does not have a pointed portion so that the upper surface does not have an initiation point of cracks. Accordingly, this embodiment can suppress the generation of cracks in the cap insulation film 115.

The structures of the first to fourth embodiments may be used in combination. For example, the air gap of the third or the fourth embodiment is applicable to the second embodiment. Further, the air gaps of the first to third embodiments and the air gap of the fourth embodiment may be formed in the same semiconductor device. In this case, the semiconductor device has both the first and second air gaps.

Further, in the first to fourth embodiments, by forming the cap insulation film 115 by a coating method, the height of the upper end of the air gap 116 is set lower than the height of the upper surface of the wire 121. However, it may be possible to realize such structure by forming the cap insulation film 115 using other methods.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate;
a plurality of wires each of which includes a wire
material layer formed on the semiconductor substrate; and
a cap insulation film formed on the wires such that an a gap void is formed between the wires, wherein
a height of an upper end of the gap void is set lower than height of an upper surface of the wire.

2. The semiconductor device of claim 1, wherein the gap void spans the entire space between adjacent wires.

3. The semiconductor device of claim 1, wherein the gap void spans only a portion of the space between the wires.

4. A semiconductor device, comprising:
a substrate;
a plurality of wires formed on the substrate, the wires comprising at least a first wire and a second wire, wherein the second wire is substantially parallel to the first wire and separated from the first wire by a first inter-wire width, each of the first wire and the second wire having a first wire height; and
a cap insulation layer formed over the wires, such that an air gap is formed between the first and second wire, the air gap having a gap width, the gap width measured at the widest point of the air gap between the wires, and an upper surface, the upper surface having a first gap height measured from where the upper surface contacts the first wire and a second gap height measured at the highest point of the upper surface between the first and second wires.

5. The device of claim 4, wherein the first gap height is less than first wire height.

6. The device of claim 4, wherein both the first gap height and the second gap height are less than the first wire height.

7. The device of claim 4, wherein the first gap height equals the second gap height and the upper surface is substantially flat.

8. The device of claim 4, wherein the first gap height is less than the second gap height and the upper surface forms a convex shape.

9. The device of claim 4, wherein the gap width is less than first inter-wire width.

10. The device of claim 9, wherein the upper surface does not span from the first wire to the second wire, but rather spans from the first wire at the first gap height to a point on the substrate the gap width distance from the first wire.

11. The device of claim 4, wherein the first inter-wire width is less than 200 nanometers.

12. The device of claim 4, wherein the cap insulation layer is formed by a coating method.

13. The device of claim 4, wherein the cap insulation layer is carbon doped silicon oxide.

14. The device of claim 4, wherein the cap insulation layer comprises silicon, carbon, oxygen, and hydrogen.

15. The device of claim 4, the plurality of wires further comprising:
a third wire; and
a fourth wire, substantially parallel to the third wire and separated by a second inter-wire width, the second inter-wire width greater than the first inter-wire width, such that second inter-wire width is sufficient to allow the cap insulation layer to completely fill the region between the third wire and fourth wire.

16. The device of claim 15, wherein the second inter-wire width is 200 nanometers or greater.

17. A method of making a semiconductor device, comprising:
forming a plurality of wires on a substrate, the wires comprising at least a first wire and a second wire, wherein the second wire is substantially parallel to the first wire and separated from the first wire by a first inter-wire width, each of the first wire and the second wire having a first wire height; and
forming a cap insulation layer over the wires, such that an air gap is formed between the first and second wire, the air gap having a gap width and an upper surface, the upper surface having a first gap height measured from where the upper surface contacts either the first or second wire.

18. The method of claim 17, wherein forming the cap insulation layer over the wires is done with a coating method.

19. The method of claim 17, wherein in first gap height is less than the first wire height.

20. The method of claim 17, wherein the plurality of wires on the substrate further includes a third wire and a fourth wire, the fourth wire substantially parallel to the third wire and separated by a second inter-wire width, the second inter-wire width greater than the first inter-wire width, such that second inter-wire width is sufficient to allow the cap insulation layer to completely fill the region between the third wire and fourth wire.
